(19) United States
(12) Patent Application Publication
(10) Pub. No.: US 2014/0303379 A1
(43) Pub. Date: Oct. 9, 2014

(54) LUMINESCENT SOLAR CONCENTRATOR COMPRISING DISUBSTITUTED BENZOSELENADIAZOLE COMPOUNDS

(71) Applicants: Samuele Santarelli, Novara (IT); Roberto Fusco, Novara (IT); Antonio Proto, Novara (IT); Luciano Caccianotti, Biandrate (IT)

(72) Inventors: Samuele Santarelli, Novara (IT); Roberto Fusco, Novara (IT); Antonio Proto, Novara (IT); Luciano Caccianotti, Biandrate (IT)

(21) Appl. No.: 14/128,987

(22) PCT Filed: Jul. 5, 2012
(86) PCT No.: PCT/IB2012/053432

§ 371 Date: May 14, 2014

(30) Foreign Application Priority Data
Jul. 7, 2011 (IT) MI2011A001268

(51) Int. Cl. H01L 51/00

(52) U.S. Cl. CPC H01L 51/0068; H01L 51/0071
USPC 548/121

(57) ABSTRACT

Luminescent solar concentrator (LSC) comprising at least one disubstituted benzoselenadiazole compound having general formula (I): R₁, R₂, R₃, R₄ and R₅, equal to or different from each other, represent a hydrogen atom; or they are selected from linear or branched C₁-C₂₀, preferably C₁-C₁₀, alkyl groups, cycloalkyl groups optionally substituted, aryl groups optionally substituted, linear or branched C₁-C₂₀, preferably C₁-C₁₀, alkoxyl groups, optionally substituted; or R₁ and R₂, can be possibly bound to each other so as to form, together with the carbon atoms to which they are bound, a cycle or a polycyclic system containing from 3 to 14 carbon atoms, preferably from 4 to 6 carbon atoms, saturated, unsaturated, or aromatic, possibly containing one or more heteroatoms such as, for example, oxygen, sulfur, nitrogen, silicon, phosphorous, selenium; or R₃ and R₄, can be possibly bound to each other so as to form, together with the carbon atoms to which they are bound, a cycle or a polycyclic system containing from 3 to 14 carbon atoms, preferably from 4 to 6 carbon atoms, saturated, unsaturated, or aromatic, possibly containing one or more heteroatoms such as, for example, oxygen, sulfur, nitrogen, silicon, phosphorous, selenium; or R₄ and R₅, can be possibly bound to each other so as to form, together with the carbon atoms to which they are bound, a cycle or a polycyclic system containing from 3 to 14 carbon atoms, preferably from 4 to 6 carbon atoms, saturated, unsaturated, or aromatic, possibly containing one or more heteroatoms such as, for example, oxygen, sulfur, nitrogen, silicon, phosphorous, selenium.

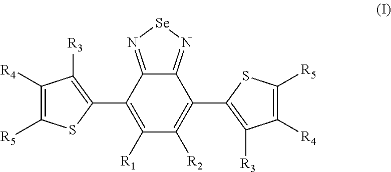

The present invention relates to a luminescent solar concentrator (LSC) comprising at least one disubstituted benzoselenadiazole compound.

The present invention also relates to the use of at least one disubstituted benzoselenadiazole compound in the construction of luminescent solar concentrators (LSC).

The present invention also relates to photovoltaic device selected, for example, from photovoltaic cells, photovoltaic modules, solar cells, solar modules, on both rigid and flexible supports, comprising a luminescent solar concentrator (LSC) including at least one disubstituted benzoselenadiazole compound.

It is known that single-junction photovoltaic cells are not capable of efficiently exploiting all solar radiation. Their efficiency, in fact, is maximum only within a certain spectrum range which comprises a part of visible radiation and a part of infrared radiation.

Spectrum convertor materials which capture solar radiation outside the optimal spectral range and convert it to effective radiation, can be used for enhancing the performance of photovoltaic cells. Furthermore, luminescent solar concentrators (LSCs) can be produced with these materials, which allow a further increase in the production of current in photovoltaic cells.

Said luminescent solar concentrators (LSCs) generally consist of large sheets of material transparent to solar radiation, in which fluorescent substances are dispersed or chemically bound to said material, which act as spectrum converters. Due to the effect of the optical phenomenon of total reflection, the radiation emitted by the fluorescent molecules is “guided” towards the thin edges of the sheet where it is concentrated on photovoltaic cells or solar cells positioned therein. In this way, large surfaces of low-cost materials (photoluminescent sheets) can be used for concentrating the light on small surfaces of high-cost materials (photovoltaic cells or solar cells).

A fluorescent compound should have numerous characteristics for being advantageously used in the construction of luminescent solar concentrators (LSCs) and these are not always compatible with each other.

First of all, the frequency of the radiation emitted by fluorescence must correspond to an energy higher than the threshold value below which the semiconductor, representing the core of the photovoltaic cell, is no longer able to function.

Secondly, the absorption spectrum of the fluorescent compound should be as extensive as possible, so as to absorb most of the striking solar radiation and then re-emit it at the desired frequency.

It is also desirable that the absorption of the solar radiation be extremely intense, so that the fluorescent compound can exert its function at the lowest possible concentrations, avoiding the use of large quantities.

Furthermore, the absorption process of solar radiation and its subsequent re-emission at lower frequencies, must take place with the highest possible efficiency, minimizing so-called non-radiative losses, often collectively indicated with the term “thermalization”: the efficiency of the process is measured by its quantic yield.

Finally, the absorption and emission frequencies must be as diverse as possible, as otherwise the radiation emitted by a molecule of the fluorescent compound would be absorbed and at least partially diffused by the adjacent molecules. This phenomenon, normally called self-absorption, inevitably leads to a significant loss in efficiency. The difference between the frequencies of the peak with a lower frequency of the absorption spectrum and the peak of the radiation emitted, is normally indicated as Stokes “shift” and measured as nm (it, is not the difference between the two. frequencies that is measured, but the difference between the two wavelengths which correspond to them). High Stokes shifts are absolutely necessary for obtaining high efficiencies of luminescent solar concentrators (LSCs), bearing in mind the necessity, already mentioned, that the frequency of the radiation emitted correspond to an energy higher than the threshold value below which the photovoltaic cell is not able to function.

It is known that some benzothiadiazole compounds, in particular 4,7-di-(thien-2′-yl)-2,1,3-benzothiadiazole (DTB), are fluorescent compounds which can be used in the construction of luminescent solar concentrators (LSCs). Compounds of this type are described in Italian patent application MI 2009 A 001796 in the name of the Applicant.

4,7-di-(thien-2′-yl)-2,1,3-benzothiadiazole (DTB) is characterized by an emission centred around 579 nm, which corresponds to an energy well above the minimum threshold value for the functioning of photovoltaic cells, said threshold corresponding for example to a wavelength of about 1100 nm for the most widely-used cells, based on silicon. Furthermore, its absorption of light radiation is intense and extends over a relatively wide range of wavelengths, indicatively ranging from 550 nm (green radiation wavelength) to ultraviolet. Finally, 4,7-di-(thien-2′-yl)-2,1,3-benzothiadiazole (DTB) has a Stokes shift in dichloromethane solution, equal to 133 nm, well above that of most of the commercial products so far proposed for use in luminescent solar concentrators.

For these reasons, the use of 4,7-di-(thien-2′-yl)-2,1,3-benzothiadiazole (DTB) has enabled the production of high-quality luminescent solar concentrators (LSCs).

Although 4,7-di-(thien-2′-yl)-2,1,3-benzothiadiazole (DTB) absorbs a significant part of the solar spectrum, however, it has a modest absorption in its higher wavelength regions, corresponding to yellow and red radiations which cannot therefore be converted into other radiations more effectively exploited by the photovoltaic cell. For this reason, it is desirable to avail of fluorescent compounds having a wider absorption spectrum towards red.

The Applicant has therefore considered the problem of finding compounds having a wider absorption spectrum towards red.

The Applicant has now found that disubstituted benzoselenadiazole compounds having a specific general formula (i.e. having general formula (I) indicated hereunder) can be advantageously used in the construction of luminescent solar concentrators (LSCs).

Said luminescent solar concentrators LSC can be advantageously used in the construction of photovoltaic devices such as, for example, photovoltaic cells, photovoltaic modules, solar cells, solar modules, on rigid and flexible supports. Said disubstituted benzoselenadiazole compounds, in fact, have an absorption spectrum which extends much more towards red with respect to known benzothiadiazole compounds.

Furthermore, said disubstituted benzoselenadiazole compounds have higher Stokes shifts than those of the known benzothiadiazole compounds.

An object of the present invention therefore relates to a luminescent solar concentrator (LSC) comprising at least one disubstituted benzoselenadiazole compound having general formula (I),

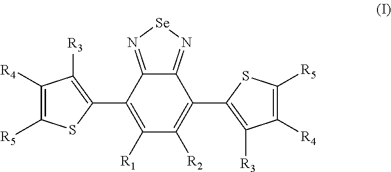

wherein:
R₁, R₂, R₃, R₄ and R₅, equal to or different from each other, represent a hydrogen atom; or they are selected from linear or branched C₁-C₂₀, preferably alkyl groups, cycloalkyl groups optionally substituted, aryl groups optionally substituted, linear or branched C₁-C₂₀, preferably C₁-C₁₀, alkoxyl groups, optionally substituted;
or R₁ and R₂, can be possibly bound to each other so as to form, together with the carbon atoms to which they are bound, a cycle or a polycyclic system containing from 3 to 14 carbon atoms, preferably from 4 to 6 carbon atoms, saturated, unsaturated, or aromatic, possibly containing one or more heteroatoms such as, for example, oxygen, sulfur, nitrogen, silicon, phosphorous, selenium;
or R₃ and R₄, can be possibly bound to each other so as to form, together with the carbon atoms to which they are bound, a cycle or a polycyclic system containing from 3 to 14 carbon atoms, preferably from 4 to 6 carbon atoms, saturated, unsaturated, or aromatic, possibly containing one or more heteroatoms such as, for example, oxygen, sulfur, nitrogen, silicon, phosphorous, selenium;
or R₄ and R₅, can be possibly bound to each other so as to form, together with the carbon atoms to which they are bound, a cycle or a polycyclic system containing from 3 to 14 carbon atoms, preferably from 4 to 6 carbon atoms, saturated, unsaturated, or aromatic, possibly containing one or more heteroatoms such as, for example, oxygen, sulfur, nitrogen, silicon, phosphorous, selenium.

According to a preferred embodiment of the present invention, in said general formula (I) the substituents R₁, R₂, R₃, R₄ and R₅ represent a hydrogen atom.

A particularly preferred aspect of the present invention therefore relates to a luminescent solar concentrator (LSC) comprising 4,7-di-(tien-2′-yl)-2,1,3-benzoselenadiazole having formula (Ia)

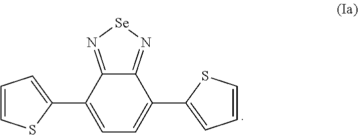 [SMILES: c1csc(-c2ccc(-c3cccs3)c3n[se]nc23)c1]

As mentioned above, the benzoselenadiazole compound having general formula (I), has an adsorption which, with respect to that of 4,7-di-(thien-2′-yl)-2,1,3-benzothiadiazole (DTB) which significantly extends more towards red: this absorption is intense and extensive over a relatively wide wavelength range which, for example, for 4,7-di-(thien-2′-yl)-2,1,3-benzoselenadiazole having formula (Ia) ranges from 230 nm to 590 nm.

Furthermore, said compound having general formula (I) has a particularly high Stokes shift high. 4,7-di-(thien-2′-yl)-2,1,3-benzoselenadiazole having formula (Ia), for example, has a Stokes shift in dichloromethane solution equal to 155 nm, therefore higher than that, already high, of 4,7-di-(thien-2′-yl)-2,1,3-benzothiadiazole.

For the purposes of the present description and following claims, the definitions of the numerical ranges always comprise the extremes unless otherwise specified.

The term “C₁-C₂₀ alkyl groups” refers to linear or branched alkyl groups having from 1 to 20 carbon atoms. Specific examples of C₁-C₂₀ alkyl groups are: methyl, ethyl, n-propyl, iso-propyl, n-butyl, iso-butyl, t-butyl, pentyl, ethyl-hexyl, hexyl, heptyl, octyl, nonyl, decyl, dodecyl.

The term “cycloalkyl groups” refers to cycloalkyl groups having from 3 to 10 carbon atoms. Said cycloalkyl groups can be optionally substituted with one or more groups, equal to or different from each other, selected from: halogen atoms such as, for example, fluorine, chlorine, preferably fluorine; hydroxyl groups; C₁-C₂₀ alkyl groups; C₁-C₂₀ alkoxyl groups; cyano groups; amino groups; nitro groups; aryl groups. Specific examples of cycloalkyl groups are: cyclopropyl, 1,4-dioxine, 2,2-difluorocyclopropyl, cyclobutyl, cyclopentyl, cyclohexyl, methylcyclohexyl, methoxycyclohexyl, fluorocyclohexyl, phenylcyclohexyl.

The term “aryl groups” means aromatic carbocyclic groups. Said aryl groups can be optionally substituted by one or more groups, equal to or different from each other, selected from: halogen atoms such as, for example, fluorine, chlorine, preferably fluorine; hydroxyl groups; C₁-C₂₀ alkyl groups; C₁-C₂₀ alkoxyl groups, cyano groups; amino groups; nitro groups; aryl groups. Specific examples of aryl groups are: phenyl, methylphenyl, trimethylphenyl, methoxyphenyl, hydroxyphenyl, phenyloxyphenyl, fluorophenyl, pentafluorophenyl, chlorophenyl, nitrophenyl, dimethylaminophenyl, naphthyl, phenylnaphthyl, phenanthrene, anthracene.

The term “C₁-C₂₀ alkoxyl groups” refers to linear or branched alkoxyl groups having from 1 to 20 carbon atoms. Said alkoxyl groups can be optionally substituted with one or more groups, equal to or different from each other, selected from: halogen atoms such as, for example, fluorine, chlorine, preferably fluorine; hydroxyl groups; C₁-C₂₀ alkyl groups; C₁-C₂₀ alkoxyl groups; cyano groups; amino groups; nitro groups. Specific examples of C₁-C₂₀ alkoxyl groups are: methoxyl, ethoxyl, fluoro-ethoxyl, n-propoxyl, iso-propoxyl, n-butoxyl, n-fluoro-butoxyl, iso-butoxyl, t-butoxyl, pentoxyl, hexyloxyl, heptyloxyl, octyloxyl, nonyloxyl, decyloxyl, dodecyloxyl.

The term “cyclo or polycyclic system” relates to a system containing one or more rings containing from 3 to 14 carbon atoms, optionally containing heteroatoms selected from nitrogen, oxygen, sulfur, silicon, selenium, phosphorous. Specific examples of a cyclo or polycyclic system are: thieno[3,2-b]thiophene, thiadiazole, benzothiophene, quinoxaline, pyridine.

Said compound having general formula (I) can be obtained according to processes known in the art as described, for example, in: “Journal of Polymer Science” Part A—Polymer Chemistry (2010), Vol. 48, pages 1423-1432. Said compound having general formula (I) can be obtained, for example, through the Stille reaction, by reacting a benzoselenadiazole compound having general formula (II) with tri-n-butyl(thien-2-yl) stannane having general formula (III), as indicated in the following scheme:

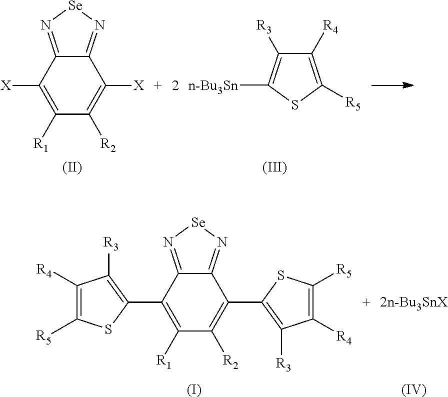

wherein X represents a halogen atom, such as, for example, chlorine, bromine, fluorine, preferably bromine, R₁, R₂, R₃, R₄ and R₅ have the same meanings indicated above. Said reaction is generally carried out in the presence of catalysts containing palladium, at temperatures ranging from 60° C. to 145° C. in the presence of solvents such as, for example, toluene, xylene, 1,2-dimethoxyethane, tetrahydrofuran, dimethylsulfoxide, N,N-dimethylformamide, for a time ranging from 35 minutes to 18 hours.

The benzoselenadiazole compound having general formula (II) can be obtained according to processes known in the art, for example, by halogenation of the corresponding benzoselenadiazole compounds. More details relating these processes can be found, for example, in “Macromolecules” (2003), Vol. 36, pages 7453-7460; “Journal of the Chemical Society, Perkin Transactions 1: Organic and Bio-Organic Chemistry” (1981), pages 607-613.

Tri-n-butyl(thien-2-yl) stannane having general formula (III), can be obtained according to processes known in the art, such as, for example, by lithiation and subsequent stannylation of the corresponding thiophene compounds. More details on these processes can be found, for example, in “Journal of the Chemical Society”, Perkin Transactions 1: Organic and Bio-Organic Chemistry” (1988), pages 2415-2422; “Journal of Polymer Science”, Part A: Polymer Chemistry” (2010), Vol. 48, pages 1714-1720. In particular, tri-n-butyl(thien-2-yl)stannane having general formula (III), wherein R₃, R₄ and R₅, are hydrogen atoms, can be easily found on the market.

A further object of the present invention relates to the use of at least one disubstituted benzoselenadiazole compound having general formula (I) in the construction of luminescent solar concentrators (LSCs).

The benzoselenadiazole compound having general formula (I) can be used in said luminescent solar concentrator (LSC) in the following forms: dispersed in the polymer or in glass, chemically bound to the polymer or glass, in solution, in gel form.

The luminescent solar concentrator (LSC) can contain, for example, a transparent matrix, wherein the term “transparent matrix” refers to any transparent material used in the form of a carrier, ligand, or a material in which at least one disubstituted benzoselenadiazole compound having general formula (I) is dispersed or englobed. The material used for the matrix is transparent, as such, to the radiations of interest and, in particular, to radiations having a frequency within the effective spectrum of the photovoltaic device (e.g. the photovoltaic cell) in which it is used. Materials suitable for the purposes of the present invention can therefore be selected from materials transparent at least to radiations having a wavelength ranging from 250 nm to 1100 nm.

The transparent matrix that can be used for the purposes of the present invention can be selected, for example, from polymeric or vitreous materials. Said matrix is characterized by a high transparency and a high duration with respect to heat and light. Polymeric materials which can be advantageously used for the purposes of the present invention are, for example, polymethylmethacrylate (PMMA), epoxy resins, silicon resins, polyalkylene terephthalates, polycarbonates, polystyrene, polypropylene. Vitreous materials which can be advantageously used for the purposes of the present invention are, for example, silicas.

If the matrix is of the polymeric type, said at least one disubstituted benzoselenadiazole compound having general formula (I) can be dispersed in the polymer of said matrix by means, for example, of melt dispersion, and subsequent formation of a sheet comprising said polymer and said at least one disubstituted benzoselenadiazole compound having general formula (I), operating, for example, according to the technique known as “casting”. Alternatively, said at least one disubstituted benzoselenadiazole compound having general formula (I) and the polymer of said matrix can be solubilized in at least one solvent obtaining a solution which is deposited on a sheet of said polymer, forming a film comprising said at least one disubstituted benzoselenadiazole compound having general formula (I) and said polymer, operating, for example, with the use of a Doctor Blade-type film applicator: said solvent is subsequently left to evaporate.

If the matrix is of the vitreous type, said at least one disubstituted benzoselenadiazole compound having general formula (I) can be solubilized in at least one solvent obtaining a solution which is deposited on a sheet of said matrix of the vitreous type, forming a film comprising said at least one disubstituted benzoselenadiazole compound having general formula (I), operating, for example, with the use of a Doctor Blade-type film applicator: said solvent is subsequently left to evaporate.

A further object of the present invention also relates to a photovoltaic device selected, for example, from photovoltaic cells, photovoltaic modules, solar cells, solar modules, on both rigid and flexible supports, comprising a luminescent solar concentrator (LSC) including at least one disubstituted benzoselenadiazole compound having general formula (I).

Said photovoltaic device can be obtained, for example, by assembling the above luminescent solar concentrator with a photovoltaic cell.

According to a preferred embodiment of the present invention, the above solar concentrator can be produced in the form of a transparent sheet obtained through the solubilization of said at least one disubstituted benzoselenadiazole compound having general formula (I) and the polymer of the matrix, of the polymeric type, in at least one solvent, obtaining a solution which is deposited on a sheet of said polymer forming a film comprising said at least one disubstituted benzoselenadiazole compound having general formula (I) and said polymer, operating, for example, with the use of a Doctor Blade-type film applicator: said solvent is subsequently left to evaporate. In said solar devices, said sheets can then be coupled with a photovoltaic cell.

Some illustrative and non-limiting examples are provided hereunder for a better understanding of the present invention and for its embodiment.

4,7-di-(thien-2′-yl)-2,1,3-benzoselenadiazole having formula (1a) was obtained as described in “Journal of Polymer Science Part A—Polymer Chemistry (2010), Vol. 48, pages 1423-1432.

4,7-di-(thien-2′-yl)-2,1,3-benzothiadiazole (DTB) was obtained as described in patent application MI 2010 A 001316 in the name of the Applicant, whose content is incorporated herein as reference.

### EXAMPLE 1

6 g of polymethylmethacrylate Altuglas VSUVT 100 (PMMA) and 57.2 mg of 4,7-di-(thien-2′-yl)-2,1,3-benzoselenadiazole, were dissolved in 30 ml of 1,2-dichlorobenzene. The solution obtained was uniformly deposited on a polymethylmethacrylate sheet Altuglas VSUVT 100 (PMMA) (dimensions 90×90×6 mm) using a Doctor Blade-type film applicator and the solvent was left to evaporate at room temperature (25° C.) in a light stream of air, for 24 hours. A red-coloured transparent sheet was obtained (sheet 1), the colour being conferred by the film, whose thickness proved to range from 300 μm to 350 μm.

A photovoltaic cell IXYS-XOD17, having a surface of 1.2 cm² was then applied to one of the edges of the polymeric sheet.

The main side of the polymeric sheet (that covered by the thin film containing 4,7-di-(thien-2′-yl)-2,1,3-benzoselenadiazole) was then illuminated, with a light source having a power of 1 sun (1000 W/m²) and the electric power generated by the illumination was measured.

The power measurements were effected by covering, with an opaque coating (cover), surfaces having variable areas of the polymeric support, at an increasing distance from the edge on which the photovoltaic cells were fixed. These measurements under variable screening conditions allow the contribution of possible waveguide, edge or multiple diffusion effects due to the support, to be quantified and consequently to be subtracted.

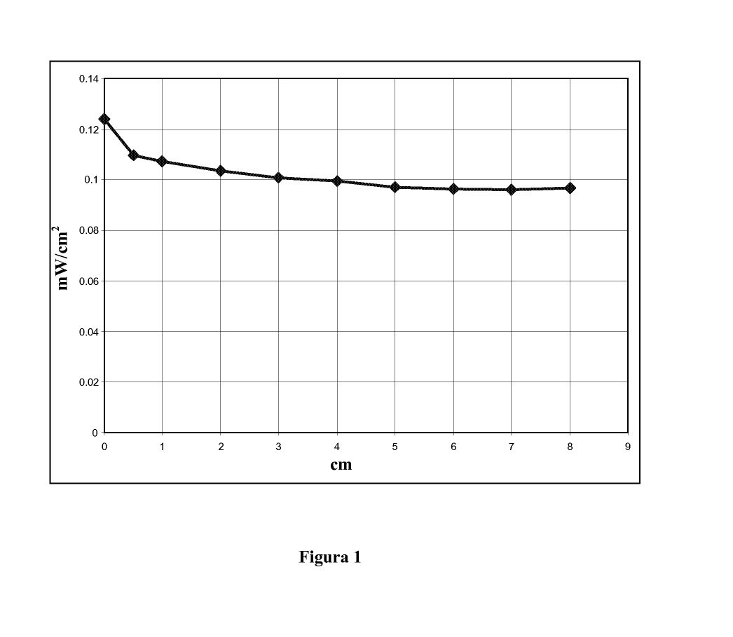

FIG. 1 shows the curve relating to the value of the power generated per unit of surface illuminated, expressed as mW/cm², in relation to the distance of the cover from the edge of the support containing the solar cell.

It can be seen that, in the absence of edge effects, the average power generated is fixed at around 0.097 mW/cm² (FIG. 1).

### EXAMPLE 2

### Comparative

6 g of polymethylmethacrylate Altuglas VSUVT 100 (PMMA) and 49.5 mg of 4,7-di-(thien-2′-yl)-2,1,3-benzothiadiazole (DTB) were dissolved in 30 ml of 1,2-dichlorobenzene. The solution obtained was then uniformly deposited on a sheet of polymethylmethacrylate Altuglas VSUVT 100 (PMMA) (dimensions 90×90×6 mm)) using a Doctor Blade-type film applicator and the solvent was left to evaporate at room temperature (25° C.) in a light stream of air, for 24 hours. A red-coloured transparent sheet was obtained (sheet 2), the colour being conferred by the film, whose thickness proved to range from 300 μm to 350 μm.

A photovoltaic cell IXYS-XOD17, having a surface of 1.2 cm² was then applied to one of the edges of the polymeric sheet.

The main side of the polymeric sheet (that covered by the thin film containing 4,7-di-(thien-2′-yl)-2,1,3-benzothiadiazole) was then illuminated with a light source having a power of 1 sun (1000 W/m²) and the electric power generated by the effect of the illumination was measured.

The power measurements were effected by covering, with an opaque coating (cover), surfaces having variable areas of the polymeric support, at an increasing distance from the edge on which the photovoltaic cells were fixed. These measurements under variable screening conditions allow the contribution of possible waveguide, edge or multiple diffusion effects due to the support, to be quantified and consequently to be subtracted.

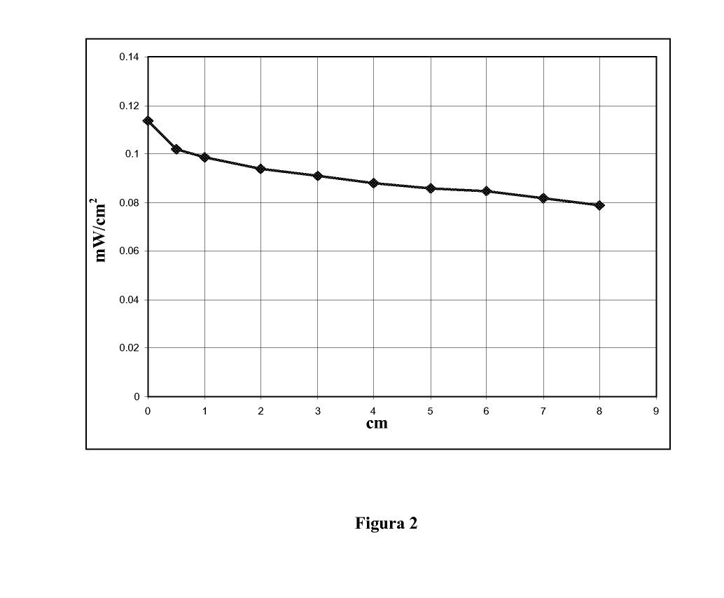

FIG. 2 shows the curve relating to the value of the power generated per unit of surface illuminated, expressed as mW/cm², in relation to the distance of the cover from the edge of the support containing the solar cell.

It can be seen that, in the absence of edge effects, the power generated is fixed at around 0.079 mW/cm² (FIG. 2) lower than that generated using 4,7-di-(thien-2′-yl)-2,1,3-benzoselenadiazole according to the present invention.

1. A luminescent solar concentrator comprising at least one disubstituted benzoselenadiazole compound having general formula (I): 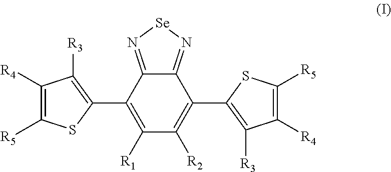
wherein:
R₁, R₂, R₃, R₄ and R₅, equal to or different from each other, represent a hydrogen atom; or they are selected from linear or branched C₁-C₂₀ alkyl groups, cycloalkyl groups optionally substituted, aryl groups optionally substituted, linear or branched C₁-C₂₀ alkoxyl groups, optionally substituted;
or R₁ and R₂, can be possibly bound to each other so as to form, together with the carbon atoms to which they are bound, a cyclic or a polycyclic system containing from 3 to 14 carbon atoms, saturated, unsaturated, or aromatic, possibly containing one or more heteroatoms;
or R₃ and R₄, can be possibly bound to each other so as to form, together with the carbon atoms to which they are bound, a cyclic or a polycyclic system containing from 3 to 14 carbon atoms, saturated, unsaturated, or aromatic, possibly containing one or more heteroatoms;
or R₄ and R₅, can be possibly bound to each other so as to form, together with the carbon atoms to which they are bound, a cyclic or a polycyclic system containing from 3 to 14 carbon atoms, saturated, unsaturated, or aromatic, possibly containing one or more heteroatoms.

2. The luminescent solar concentrator according to claim 1, wherein in said general formula (I), the substituents R₁, R₂, R₃, R₄ and R₅, represent a hydrogen atom.

3. The luminescent solar concentrator according to claim 1, wherein said disubstituted benzoselenadiazole compound having general formula (I) is 4,7-di-(thien-2′-yl)-2,1,3-benzoselenadiazole having formula (Ia):

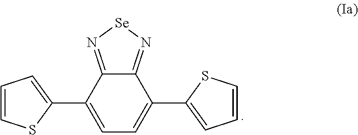

4. A method of constructing a luminescent solar concentrator (LSC) comprising: providing in a luminescent solar concentrator at least one disubstituted benzoselenadiazole compound having general formula (I): 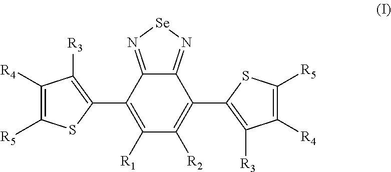
wherein:
R₁, R₂, R₃, R₄ and R₅, equal to or different from each other, represent a hydrogen atom; or they are selected from linear or branched C₁-C₂₀ alkyl groups, cycloalkyl groups optionally substituted, aryl groups optionally substituted, linear or branched C₁-C₂₀ alkoxyl groups, optionally substituted;
or R₁ and R₂, can be possibly bound to each other so as to form, together with the carbon atoms to which they are bound, a cyclic or a polycyclic system containing from 3 to 14 carbon atoms, saturated, unsaturated, or aromatic, possibly containing one or more heteroatoms;
or R₃ and R₄, can be possibly bound to each other so as to form, together with the carbon atoms to which they are bound, a cyclic or a polycyclic system containing from 3 to 14 carbon atoms, saturated, unsaturated, or aromatic, possibly containing one or more heteroatoms;
or R₄ and R₅, can be possibly bound to each other so as to form, together with the carbon atoms to which they are bound, a cyclic or a polycyclic system containing from 3 to 14 carbon atoms, saturated, unsaturated, or aromatic, possibly containing one or more heteroatoms.

5. The method according to claim 4, wherein in said general formula (I), the substituents R₁, R₂, R₃, R₄ and R₅, represent a hydrogen atom.

6. The method according to claim 4, wherein said disubstituted benzoselenadiazole compound having general formula (I) is 4,7-di-(thien-2′-yl)-2,1,3-benzoselenadiazole having formula (Ia):

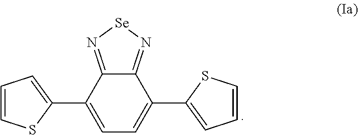

7. A photovoltaic device selected from photovoltaic cells, photovoltaic modules, solar cells, or solar modules, on both rigid and flexible supports, comprising a luminescent solar concentrator (LSC) that includes at least one disubstituted benzoselenadiazole compound having general formula (I), according to claim 1.
